(19) United States
(12) Patent Application Publication
(10) Pub. No.: US 2010/0202867 A1
(43) Pub. Date: Aug. 12, 2010

(54) SUBSTRATE PROCESSING APPARATUS

(75) Inventor: Tetsuya HAMADA, Kyoto (JP)

Correspondence Address: OSTROLENK FABER GERB & SOFFEN, 1180 AVENUE OF THE AMERICAS, NEW YORK, NY, 100368403, US

(73) Assignee: DAINIPPON SCREEN MFG.CO., LTD., Kyoto (JP)

(21) Appl. No.: 12/765,255

(22) Filed: Apr. 22, 2010

Related U.S. Application Data
(63) Continuation of application No. 11/416,036, filed on May 2, 2006.

(30) Foreign Application Priority Data
May 2, 2005 (JP) JP2005-134306

(51) Int. Cl. H01L 21/677

(52) U.S. Cl. 414/806

(57) ABSTRACT

A mode selection is carried out prior to the outward transfer of a substrate to be processed from an indexer block. When a “processing sequence priority mode” is selected, a transport path for the substrate is defined prior to the outward transfer of the substrate. The definition of the transport path is carried out by determining to which of a plurality of parallel processing parts for performing each parallel process the substrate is to be transported. Next, based on the defined transport path, an adjustment is made to a processing condition established for each substrate processing part included in the transport path. Thereafter, the unprocessed substrate is transferred outwardly from the indexer block, and is transported and processed along the defined transport path. On the other hand, when a “throughput priority mode” is selected, a substrate is transported to a vacant one of the plurality of parallel processing parts.

### BACKGROUND OF THE INVENTION

1. Field of the Invention

The present invention relates to a substrate processing apparatus for performing a resist coating process prior to exposure and a development process after the exposure upon a substrate such as a semiconductor substrate, a glass substrate for a liquid crystal display device, a glass substrate for a photomask, a substrate for an optical disk and the like.

2. Description of the Background Art

As is well known, semiconductor and liquid crystal display products and the like are fabricated by performing a series of processes including cleaning, resist coating, exposure, development, etching, interlayer insulation film formation, heat treatment, dicing and the like on the above-mentioned substrate. An apparatus which performs a resist coating process on a substrate to transfer the substrate to an exposure unit and which receives an exposed substrate from the exposure unit to perform a development process on the exposed substrate, among the above-mentioned processes, is widely used as a so-called coater-and-developer.

To increase the processing efficiency of the entire apparatus, such a coater-and-developer is often provided with a plurality of parallel processing parts for performing a process under the same condition in the same processing step. For example, a single coater-and-developer has two spinning-type resist coating processing units (spin coaters) for coating with a resist solution, and five hot plates set at the same temperature and for performing the subsequent heating process. It is effective to provide such parallel processing parts for such a step as to cause a bottleneck in terms of throughput in a series of processes, that is, for a step which requires long processing time.

However, if the same processing condition is established for a plurality of units of the same type which perform parallel processing, there is a slight difference between the plurality of units in reality. For example, if a plurality of hot plates identical in specification with each other are set at a temperature of 130° C., the actual temperature of one of the hot plates is 130.2° C., and the actual temperature of another is 129.9° C.

To solve such a problem, Japanese Patent Application Laid-Open No. 10-112487 (1998) discloses a technique for defining a plurality of parallel transport paths by bringing a substrate processing part for performing a parallel process and another substrate processing part for performing another parallel process into a one-to-one fixed correspondence. This provides a fixed substrate processing history for each of the parallel transport paths, thereby facilitating the quality control of substrates. With the progress of rapid reduction in semiconductor design rules in recent years, the required level of the quality control of the substrates has become increasingly stringent, and there has been a strong need to minimize variations in processing results between the substrates. Thus, the slight difference between the plurality of units for performing parallel processing, which has not conventionally been a problem, is now perceived as a problem because the slight difference causes the variations in processing results between the substrates. It is therefore preferred to eliminate even the slight difference between the units.

However, there are certain limits to the elimination of the difference between the units, and some difference inevitably remains uneliminated. Further, even if the processing history is fixed for each of the parallel transport paths by fixing the parallel processing parts to which substrates are transported as disclosed in Japanese Patent Application Laid-Open No. 10-112487, processing variations resulting from the difference between the units for performing the parallel processing arise between substrates which have passed through different parallel transport paths.

### SUMMARY OF THE INVENTION

The present invention is intended for a substrate processing apparatus for performing a resist coating process on a substrate to transfer the substrate to an exposure unit external to the apparatus and for performing a development process on an exposed substrate returned from the exposure unit.

According to the present invention, the substrate processing apparatus comprises: a substrate processing part group having a plurality of substrate processing parts for processing a substrate, the plurality of substrate processing parts including a plurality of parallel processing parts for performing a process under the same condition in the same processing step; an indexer part for transferring an unprocessed substrate to the substrate processing part group and for receiving a processed substrate from the substrate processing part group; a transport element for transporting a substrate to the indexer part and to the plurality of substrate processing parts; a transport path definition element for determining to which of the plurality of parallel processing parts an unprocessed substrate is to be transported to thereby previously define a transport path for the unprocessed substrate before the unprocessed substrate is transferred from the indexer part to the substrate processing part group; and a processing condition control element, based on the transport path defined by the transport path definition element, for adjusting a processing condition established for at least one of the plurality of substrate processing parts which is included in the transport path and which performs a process in a step prior to an exposure process.

The adjustment is previously made to the processing condition established for each substrate processing part to which the substrate is to be transported. This reduces variations in processing results between substrates passing through different parallel processing parts.

According to another aspect of the present invention, the substrate processing apparatus comprises: a substrate processing part group having a plurality of substrate processing parts for processing a substrate, the plurality of substrate processing parts including a plurality of parallel processing parts for performing a process under the same condition in the same processing step; an indexer part for transferring an unprocessed substrate to the substrate processing part group and for receiving a processed substrate from the substrate processing part group; a transport element for transporting a substrate to the indexer part and to the plurality of substrate processing parts; a transport path definition element for determining to which of the plurality of parallel processing parts an unprocessed substrate is to be transported to thereby previously define a transport path for the unprocessed substrate before the unprocessed substrate is transferred from the indexer part to the substrate processing part group; and a processing condition control element, based on the transport path defined by the transport path definition element, for adjusting a processing condition established for at least one of the plurality of substrate processing parts which is included in the transport path and which performs a process in a step after an exposure process.

It is therefore an object of the present invention to provide a substrate processing apparatus capable of reducing variations in processing results between substrates passing through different parallel processing parts.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a plan view of a substrate processing apparatus according to the present invention;

FIG. 2 is a front view of a liquid processing part in the substrate processing apparatus of FIG. 1;

FIG. 3 is a front view of a thermal processing part in the substrate processing apparatus of FIG. 1;

FIG. 4 is a view showing a construction around substrate rest parts in the substrate processing apparatus of FIG. 1;

FIG. 5A is a plan view of a transport robot in the substrate processing apparatus of FIG. 1;

FIG. 5B is a front view of the transport robot in the substrate processing apparatus of FIG. 1;

FIG. 6 is a block diagram schematically showing a control mechanism in the substrate processing apparatus of FIG. 1;

FIGS. 7 and 8 are diagrams showing parallel processing parts in the substrate processing apparatus of FIG. 1;

FIG. 9 is a flow chart showing a procedure for processing in the substrate processing apparatus of FIG. 1; and

FIG. 10 shows an example of defined transport paths.

### DESCRIPTION OF THE PREFERRED EMBODIMENTS

Prior to the description of a preferred embodiment according to the present invention, terms used herein will be defined. Processing units for performing on a substrate some kind of processing including a liquid process such as a resist coating process and a development process, a thermal process such as a cooling process and a heating process, an edge exposure process, and the like are generically referred to as “substrate processing parts.” The term “parallel process” refers to a process executed in parallel by a plurality of substrate processing parts which are set so as to have the same condition among a series of processes performed on a substrate. The term “parallel processing parts” refer to substrate processing parts for executing such a parallel process.

A preferred embodiment according to the present invention will now be described in detail with reference to the drawings.

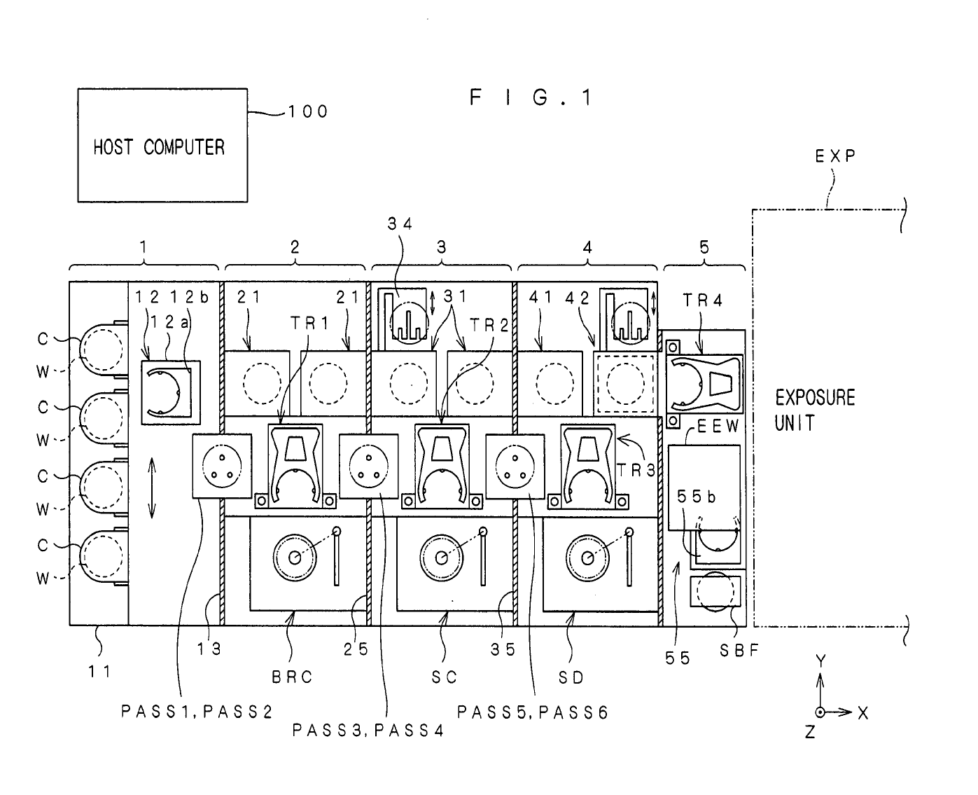

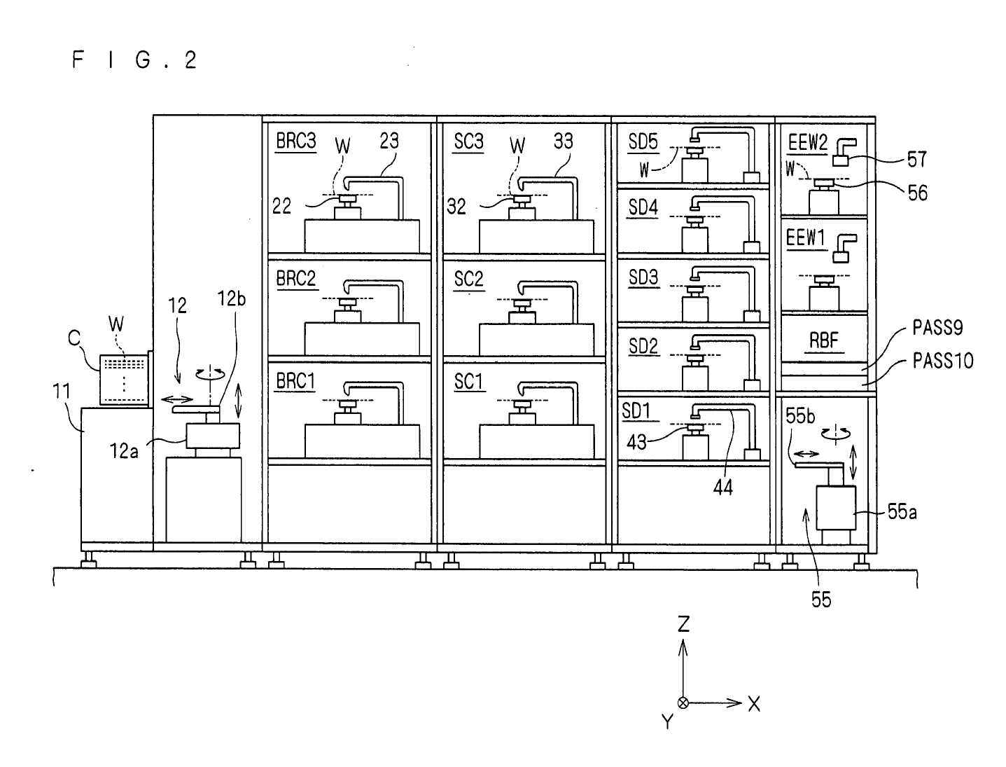

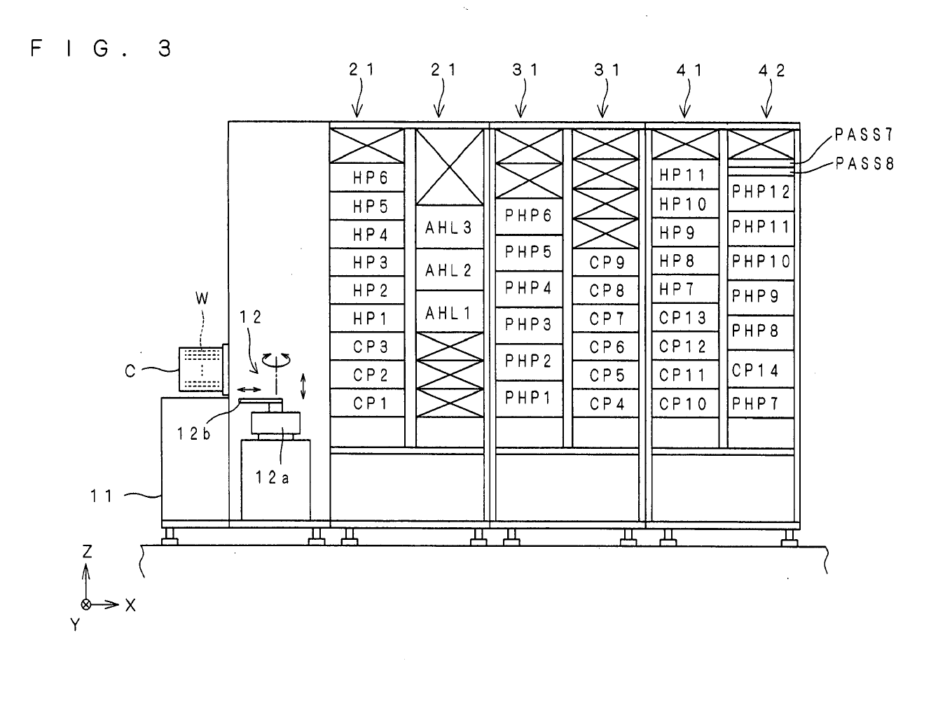

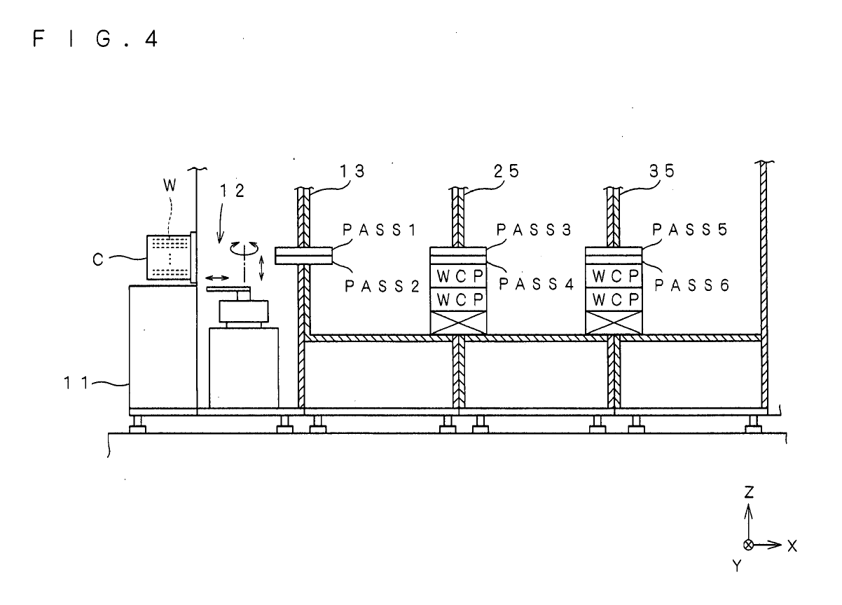

FIG. 1 is a plan view of a substrate processing apparatus according to the present invention. FIG. 2 is a front view of a liquid processing part in the substrate processing apparatus. FIG. 3 is a front view of a thermal processing part in the substrate processing apparatus. FIG. 4 is a view showing a construction around substrate rest parts in the substrate processing apparatus. An XYZ rectangular coordinate system in which an XY plane is defined as the horizontal plane and a Z axis is defined to extend in the vertical direction is additionally shown in FIGS. 1 through 4 for purposes of clarifying the directional relationship therebetween.

The substrate processing apparatus according to the preferred embodiment is an apparatus for forming an anti-reflective film and a photoresist film on substrates such as semiconductor wafers by coating and for performing a development process on substrates subjected to a pattern exposure process. The substrates to be processed by the substrate processing apparatus according to the present invention are not limited to semiconductor wafers, but may include glass substrates for a liquid crystal display device, and the like.

The substrate processing apparatus according to the preferred embodiment comprises an indexer block 1, a BARC (Bottom Anti-Reflective Coating) block 2, a resist coating block 3, a development processing block 4, and an interface block 5. In the substrate processing apparatus, the five processing blocks 1 to 5 are arranged in side-by-side relation. An exposure unit (or stepper) EXP which is an external apparatus separate from the substrate processing apparatus according to the present invention is provided and connected to the interface block 5. The substrate processing apparatus according to this preferred embodiment and the exposure unit EXP are connected via LAN lines (not shown) to a host computer 100.

The indexer block 1 is a processing block for transferring unprocessed substrates received from the outside of the substrate processing apparatus outwardly to the BARC block 2 and the resist coating block 3, and for transporting processed substrates received from the development processing block 4 to the outside of the substrate processing apparatus. The indexer block 1 comprises a table 11 for placing thereon a plurality of (in this preferred embodiment, four) cassettes (or carriers) C in juxtaposition, and a substrate transfer mechanism 12 for taking an unprocessed substrate W out of each of the cassettes C and for storing a processed substrate W into each of the cassettes C. The substrate transfer mechanism 12 includes a movable base 12a movable horizontally (in the Y direction) along the table 11, and a holding arm 12b mounted on the movable base 12a and for holding a substrate W in a horizontal position. The holding arm 12b is capable of moving vertically (in the Z direction) over the movable base 12a, pivoting within a horizontal plane and moving back and forth in the direction of the pivot radius. Thus, the substrate transfer mechanism 12 can cause the holding arm 12b to gain access to each of the cassettes C, thereby taking an unprocessed substrate W out of each cassette C and storing a processed substrate W into each cassette C. The cassettes C may be of the following types: an SMIF (standard mechanical interface) pod, and an OC (open cassette) which exposes stored substrates W to the atmosphere, in addition to a FOUP (front opening unified pod) which stores substrates W in an enclosed or sealed space.

The BARC block 2 is provided in adjacent relation to the indexer block 1. A partition 13 for closing off the communication of atmosphere is provided between the indexer block 1 and the BARC block 2. The partition 13 is provided with a pair of vertically arranged substrate rest parts PASS1 and PASS2 each for placing a substrate W thereon for the transfer of the substrate W between the indexer block 1 and the BARC block 2.

The upper substrate rest part PASS1 is used for the transport of a substrate W from the indexer block 1 to the BARC block 2. The substrate rest part PASS1 includes three support pins. The substrate transfer mechanism 12 of the indexer block 1 places an unprocessed substrate W taken out of one of the cassettes C onto the three support pins of the substrate rest part PASS1. A transport robot TR1 of the BARC block 2 to be described later receives the substrate W placed on the substrate rest part PASS 1. The lower substrate rest part PASS2, on the other hand, is used for the transport of a substrate W from the BARC block 2 to the indexer block 1. The substrate rest part PASS2 also includes three support pins. The transport robot TR1 of the BARC block 2 places a processed substrate W onto the three support pins of the substrate rest part PASS2. The substrate transfer mechanism 12 receives the substrate W placed on the substrate rest part PASS2 and stores the substrate W into one of the cassettes C. Pairs of substrate rest parts PASS3 to PASS10 to be described later are similar in construction to the pair of substrate rest parts PASS1 and PASS2.

The substrate rest parts PASS1 and PASS2 extend through the partition 13. Each of the substrate rest parts PASS1 and PASS2 includes an optical sensor (not shown) for detecting the presence or absence of a substrate W thereon. Based on a detection signal from each of the sensors, a judgment is made as to whether or not the substrate transfer mechanism 12 and the transport robot TR1 of the BARC block 2 stand ready to transfer and receive a substrate W to and from the substrate rest parts PASS1 and PASS2.

Next, the BARC block 2 will be described. The BARC block 2 is a processing block for forming an anti-reflective film by coating at the bottom of a photoresist film (i.e., as an undercoating film for the photoresist film) to reduce standing waves or halation occurring during exposure. The BARC block 2 comprises a bottom coating processor BRC for coating the surface of a substrate W with the anti-reflective film, a pair of thermal processing towers 21 for performing a thermal process which accompanies the formation of the anti-reflective film by coating, and the transport robot TR1 for transferring and receiving a substrate W to and from the bottom coating processor BRC and the pair of thermal processing towers 21.

In the BARC block 2, the bottom coating processor BRC and the pair of thermal processing towers 21 are arranged on opposite sides of the transport robot TR1. Specifically, the bottom coating processor BRC is on the front side of the substrate processing apparatus, and the pair of thermal processing towers 21 are on the rear side thereof. Additionally, a thermal barrier not shown is provided on the front side of the pair of thermal processing towers 21. Thus, the thermal effect of the pair of thermal processing towers 21 upon the bottom coating processor BRC is avoided by spacing the bottom coating processor BRC apart from the pair of thermal processing towers 21 and by providing the thermal barrier.

As shown in FIG. 2, the bottom coating processor BRC includes three coating processing units BRC1, BRC2 and BRC3 similar in construction to each other and arranged in stacked relation in bottom-to-top order. The three coating processing units BRC1, BRC2 and BRC3 are collectively referred to as the bottom coating processor BRC, unless otherwise identified. Each of the coating processing units BRC1, BRC2 and BRC3 includes a spin chuck 22 for rotating a substrate W in a substantially horizontal plane while holding the substrate W in a substantially horizontal position under suction, a coating nozzle 23 for applying a coating solution for the anti-reflective film onto the substrate W held on the spin chuck 22, a spin motor (not shown) for rotatably driving the spin chuck 22, a cup (not shown) surrounding the substrate W held on the spin chuck 22, and the like.

As shown in FIG. 3, one of the thermal processing towers 21 which is closer to the indexer block 1 includes six hot plates HP1 to HP6 for heating a substrate W up to a predetermined temperature, and cool plates CP1 to CP3 for cooling a heated substrate W down to a predetermined temperature and maintaining the substrate W at the predetermined temperature. The cool plates CP1 to CP3 and the hot plates HP1 to HP6 are arranged in stacked relation in bottom-to-top order in this thermal processing tower 21. The other of the thermal processing towers 21 which is farther from the indexer block 1 includes three adhesion promotion processing parts AHL1 to AHL3 arranged in stacked relation in bottom-to-top order for thermally processing a substrate W in a vapor atmosphere of HMDS (hexamethyl disilazane) to promote the adhesion of the resist film to the substrate W. The locations indicated by the cross marks (x) in FIG. 3 are occupied by a piping and wiring section or reserved as empty space for future addition of processing units.

Thus, stacking the coating processing units BRC1 to BRC3 and the thermal processing units (the hot plates HP1 to HP6, the cool plates CP1 to CP3, and the adhesion promotion processing parts AHL1 to AHL3 in the BARC block 2) in tiers provides smaller space occupied by the substrate processing apparatus to reduce the footprint thereof. The side-by-side arrangement of the pair of thermal processing towers 21 is advantageous in facilitating the maintenance of the thermal processing units and in eliminating the need for extension of ducting and power supply equipment necessary for the thermal processing units to a much higher position.

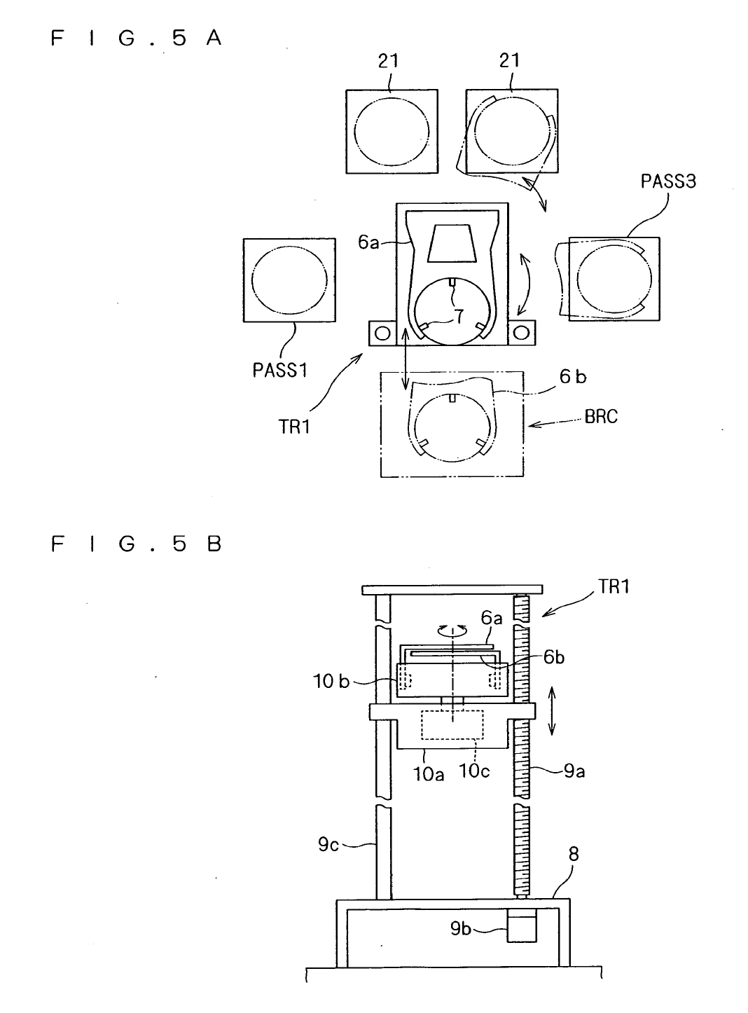

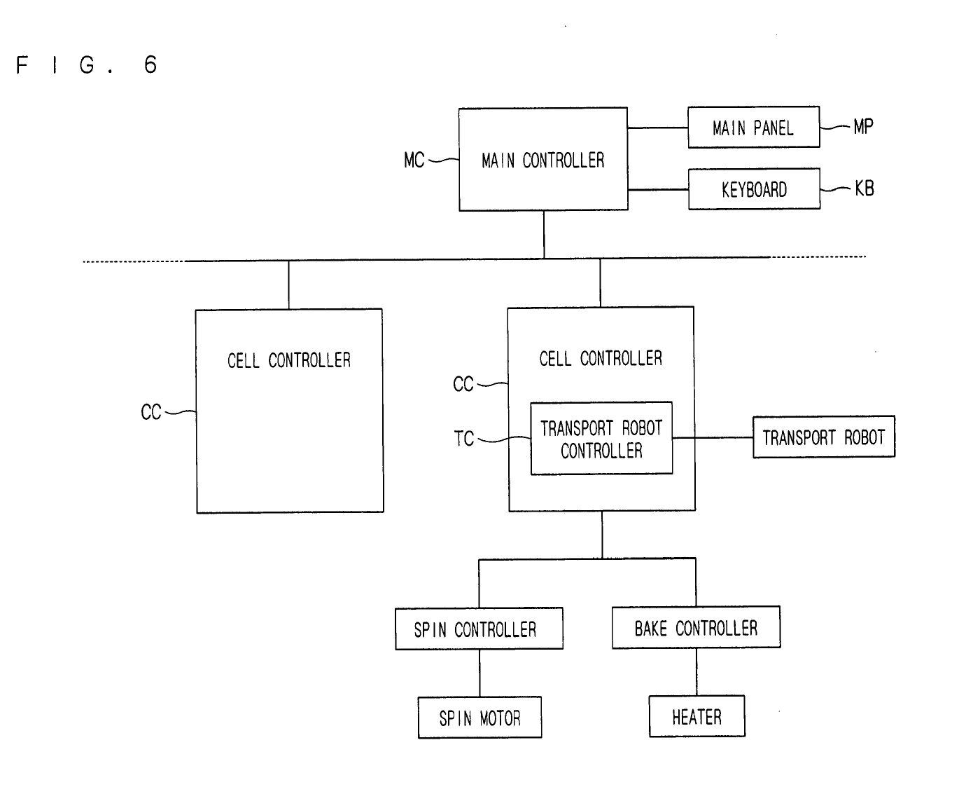

FIGS. 5A and 5B are views for illustrating the transport robot TR1. FIG. 5A is a plan view of the transport robot TR1, and FIG. 5B is a front view of the transport robot TR1. The transport robot TRI includes a pair of (upper and lower) holding arms 6a and 6b in proximity to each other for holding a substrate W in a substantially horizontal position. Each of the holding arms 6a and 6b includes a distal end portion of a substantially C-shaped plan configuration, and a plurality of pins 7 projecting inwardly from the inside of the substantially C-shaped distal end portion for supporting the peripheral edge of a substrate W from below.

The transport robot TR1 further includes a base 8 fixedly mounted on an apparatus base (or an apparatus frame). A guide shaft 9c is mounted upright on the base 8, and a threaded shaft 9a is rotatably mounted and supported upright on the base 8. A motor 9b for rotatably driving the threaded shaft 9a is fixedly mounted to the base 8. A lift 10a is in threaded engagement with the threaded shaft 9a, and is freely slidable relative to the guide shaft 9c. With such an arrangement, the motor 9b rotatably drives the threaded shaft 9a, whereby the lift 10a is guided by the guide shaft 9c to move up and down in a vertical direction (in the Z direction).

An arm base 10b is mounted on the lift 10a pivotably about a vertical axis. The lift 10a contains a motor 10c for pivotably driving the arm base 10b. The pair of (upper and lower) holding arms 6a and 6b described above are provided on the arm base 10b. Each of the holding arms 6a and 6b is independently movable back and forth in a horizontal direction (in the direction of the pivot radius of the arm base 10b) by a sliding drive mechanism (not shown) mounted to the arm base 10b.

With such an arrangement, the transport robot TR1 is capable of causing each of the pair of holding arms 6a and 6b to independently gain access to the substrate rest parts PASS1 and PASS2, the thermal processing units provided in the thermal processing towers 21, the coating processing units provided in the bottom coating processor BRC, and the substrate rest parts PASS3 and PASS4 to be described later, thereby transferring and receiving substrates W to and from the above-mentioned parts and units, as shown in FIG. 5A.

Next, the resist coating block 3 will be described. The resist coating block 3 is provided so as to be sandwiched between the BARC block 2 and the development processing block 4. A partition 25 for closing off the communication of atmosphere is also provided between the resist coating block 3 and the BARC block 2. The partition 25 is provided with the pair of vertically arranged substrate rest parts PASS3 and PASS4 each for placing a substrate W thereon for the transfer of the substrate W between the BARC block 2 and the resist coating block 3. The substrate rest parts PASS3 and PASS4 are similar in construction to the above-mentioned substrate rest parts PASS 1 and PASS2.

The upper substrate rest part PASS3 is used for the transport of a substrate W from the BARC block 2 to the resist coating block 3. Specifically, a transport robot TR2 of the resist coating block 3 receives the substrate W placed on the substrate rest part PASS3 by the transport robot TR1 of the BARC block 2. The lower substrate rest part PASS4, on the other hand, is used for the transport of a substrate W from the resist coating block 3 to the BARC block 2. Specifically, the transport robot TR1 of the BARC block 2 receives the substrate W placed on the substrate rest part PASS4 by the transport robot TR2 of the resist coating block 3.

The substrate rest parts PASS3 and PASS4 extend through the partition 25. Each of the substrate rest parts PASS3 and PASS4 includes an optical sensor (not shown) for detecting the presence or absence of a substrate W thereon. Based on a detection signal from each of the sensors, a judgment is made as to whether or not the transport robots TR1 and TR2 stand ready to transfer and receive a substrate W to and from the substrate rest parts PASS3 and PASS4. A pair of (upper and lower) cool plates WCP of a water-cooled type for roughly cooling a substrate W are provided under the substrate rest parts PASS3 and PASS4, and extend through the partition 25.

The resist coating block 3 is a processing block for applying a resist onto a substrate W coated with the anti-reflective film by the BARC block 2 to form a resist film. In this preferred embodiment, a chemically amplified resist is used as the photoresist. The resist coating block 3 comprises a resist coating processor SC for forming the resist film by coating on the anti-reflective film serving as the undercoating film, a pair of thermal processing towers 31 for performing a thermal process which accompanies the resist coating process, and the transport robot TR2 for transferring and receiving a substrate W to and from the resist coating processor SC and the pair of thermal processing towers 31.

In the resist coating block 3, the resist coating processor SC and the pair of thermal processing towers 31 are arranged on opposite sides of the transport robot TR2. Specifically, the resist coating processor SC is on the front side of the substrate processing apparatus, and the pair of thermal processing towers 31 are on the rear side thereof. Additionally, a thermal barrier not shown is provided on the front side of the pair of thermal processing towers 31. Thus, the thermal effect of the pair of thermal processing towers 31 upon the resist coating processor SC is avoided by spacing the resist coating processor SC apart from the pair of thermal processing towers 31 and by providing the thermal barrier.

As shown in FIG. 2, the resist coating processor SC includes three coating processing units SC1, SC2 and SC3 similar in construction to each other and arranged in stacked relation in bottom-to-top order. The three coating processing units SC1, SC2 and SC3 are collectively referred to as the resist coating processor SC, unless otherwise identified. Each of the coating processing units SC1, SC2 and SC3 includes a spin chuck 32 for rotating a substrate W in a substantially horizontal plane while holding the substrate W in a substantially horizontal position under suction, a coating nozzle 33 for applying a resist solution onto the substrate W held on the spin chuck 32, a spin motor (not shown) for rotatably driving the spin chuck 32, a cup (not shown) surrounding the substrate W held on the spin chuck 32, and the like.

As shown in FIG. 3, one of the thermal processing towers 31 which is closer to the indexer block 1 includes six heating parts PHP1 to PHP6 arranged in stacked relation in bottom-to-top order for heating a substrate W up to a predetermined temperature. The other of the thermal processing towers 31 which is farther from the indexer block 1 includes cool plates CP4 to CP9 arranged in stacked relation in bottom-to-top order for cooling a heated substrate W down to a predetermined temperature and maintaining the substrate W at the predetermined temperature.

Each of the heating parts PHP1 to PHP6 is a thermal processing unit including, in addition to an ordinary hot plate for heating a substrate W placed thereon, a temporary substrate rest part for placing a substrate W in an upper position spaced apart from the hot plate, and a local transport mechanism 34 (see FIG. 1) for transporting a substrate W between the hot plate and the temporary substrate rest part. The local transport mechanism 34 is capable of moving vertically and moving back and forth, and includes a mechanism for cooling down a substrate W being transported by circulating cooling water therein.

The local transport mechanism 34 is provided on the opposite side of the above-mentioned hot plate and the temporary substrate rest part from the transport robot TR2, that is, on the rear side of the substrate processing apparatus. The temporary substrate rest part has both an open side facing the transport robot TR2 and an open side facing the local transport mechanism 34. The hot plate, on the other hand, has only an open side facing the local transport mechanism 34, and a closed side facing the transport robot TR2. Thus, both of the transport robot TR2 and the local transport mechanism 34 can gain access to the temporary substrate rest part, but only the local transport mechanism 34 can gain access to the hot plate.

A substrate W is transported into each of the above-mentioned heating parts PHP1 to PHP6 in a manner to be described below. First, the transport robot TR2 places a substrate W onto the temporary substrate rest part. Subsequently, the local transport mechanism 34 receives the substrate W from the temporary substrate rest part to transport the substrate W to the hot plate. The hot plate performs a heating process on the substrate W. The local transport mechanism 34 takes out the substrate W subjected to the heating process by the hot plate, and transports the substrate W to the temporary substrate rest part. During the transport, the substrate W is cooled down by the cooling function of the local transport mechanism 34. Thereafter, the transport robot TR2 takes out the substrate W subjected to the heating process and transported to the temporary substrate rest part.

As discussed above, the transport robot TR2 transfers and receives the substrate W to and from only the temporary substrate rest part held at room temperature in each of the heating parts PHP1 to PHP6, but does not transfer and receive the substrate W directly to and from the hot plate. This avoids the temperature rise of the transport robot TR2. The hot plate having only the open side facing the local transport mechanism 34 prevents the heat atmosphere leaking out of the hot plate from affecting the transport robot TR2 and the resist coating processor SC. The transport robot TR2 transfers and receives a substrate W directly to and from the cool plates CP4 to CP9.

The transport robot TR2 is precisely identical in construction with the transport robot TR1. Thus, the transport robot TR2 is capable of causing each of a pair of holding arms thereof to independently gain access to the substrate rest parts PASS3 and PASS4, the thermal processing units provided in the thermal processing towers 31, the coating processing units provided in the resist coating processor SC, and the substrate rest parts PASS5 and PASS6 to be described later, thereby transferring and receiving substrates W to and from the above-mentioned parts and units.

Next, the development processing block 4 will be described. The development processing block 4 is provided so as to be sandwiched between the resist coating block 3 and the interface block 5. A partition 35 for closing off the communication of atmosphere is also provided between the resist coating block 3 and the development processing block 4. The partition 35 is provided with the pair of vertically arranged substrate rest parts PASS5 and PASS6 each for placing a substrate W thereon for the transfer of the substrate W between the resist coating block 3 and the development processing block 4. The substrate rest parts PASS5 and PASS6 are similar in construction to the above-mentioned substrate rest parts PASS1 and PASS2.

The upper substrate rest part PASS5 is used for the transport of a substrate W from the resist coating block 3 to the development processing block 4. Specifically, a transport robot TR3 of the development processing block 4 receives the substrate W placed on the substrate rest part PASS5 by the transport robot TR2 of the resist coating block 3. The lower substrate rest part PASS6, on the other hand, is used for the transport of a substrate W from the development processing block 4 to the resist coating block 3. Specifically, the transport robot TR2 of the resist coating block 3 receives the substrate W placed on the substrate rest part PASS6 by the transport robot TR3 of the development processing block 4.

The substrate rest parts PASS5 and PASS6 extend through the partition 35. Each of the substrate rest parts PASS5 and PASS6 includes an optical sensor (not shown) for detecting the presence or absence of a substrate W thereon. Based on a detection signal from each of the sensors, a judgment is made as to whether or not the transport robots TR2 and TR3 stand ready to transfer and receive a substrate W to and from the substrate rest parts PASS5 and PASS6. A pair of (upper and lower) cool plates WCP of a water-cooled type for roughly cooling a substrate W are provided under the substrate rest parts PASS5 and PASS6, and extend through the partition 35.

The development processing block 4 is a processing block for performing a development process on an exposed substrate W. The development processing block 4 comprises a development processor SD for applying a developing solution onto a substrate W exposed in a pattern to perform the development process, a pair of thermal processing towers 41 and 42 for performing a thermal process which accompanies the development process, and the transport robot TR3 for transferring and receiving a substrate W to and from the development processor SD and the pair of thermal processing towers 41 and 42. The transport robot TR3 is precisely identical in construction to the above-mentioned transport robots TR1 and TR2.

As shown in FIG. 2, the development processor SD includes five development processing units SD1, SD2, SD3, SD4 and SD5 similar in construction to each other and arranged in stacked relation in bottom-to-top order. The five development processing units SD1 to SD5 are collectively referred to as the development processor SD, unless otherwise identified. Each of the development processing units SD1 to SD5 includes a spin chuck 43 for rotating a substrate W in a substantially horizontal plane while holding the substrate W in a substantially horizontal position under suction, a nozzle 44 for applying the developing solution onto the substrate W held on the spin chuck 43, a spin motor (not shown) for rotatably driving the spin chuck 43, a cup (not shown) surrounding the substrate W held on the spin chuck 43, and the like.

As shown in FIG. 3, the thermal processing tower 41 which is closer to the indexer block 1 includes five hot plates HP7 to HP11 for heating a substrate W up to a predetermined temperature, and cool plates CP10 to CP13 for cooling a heated substrate W down to a predetermined temperature and maintaining the substrate W at the predetermined temperature. The cool plates CP10 to CP13 and the hot plates HP7 to HP11 are arranged in stacked relation in bottom-to-top order in this thermal processing tower 41. The thermal processing tower 42 which is farther from the indexer block 1, on the other hand, includes six heating parts PHP7 to PHP12 and a cool plate CP14 which are arranged in stacked relation. Like the above-mentioned heating parts PHP1 to PHP6, each of the heating parts PHP7 to PHP12 is a thermal processing unit including a temporary substrate rest part and a local transport mechanism. However, the temporary substrate rest part of each of the heating parts PHP7 to PHP12 and the cool plate CP14 have an open side facing a transport robot TR4 of the interface block 5, and a closed side facing the transport robot TR3 of the development processing block 4. In other words, the transport robot TR4 of the interface block 5 can gain access to the heating parts PHP7 to PHP12 and the cool plate CP14, but the transport robot TR3 of the development processing block 4 cannot gain access thereto. The transport robot TR3 of the development processing block 4 gains access to the thermal processing units incorporated in the thermal processing tower 41.

The pair of vertically arranged substrate rest parts PASS7 and PASS8 in proximity to each other for the transfer of a substrate W between the development processing block 4 and the interface block 5 adjacent thereto are incorporated in the top tier of the thermal processing tower 42. The upper substrate rest part PASS7 is used for the transport of a substrate W from the development processing block 4 to the interface block 5. Specifically, the transport robot TR4 of the interface block 5 receives the substrate W placed on the substrate rest part PASS7 by the transport robot TR3 of the development processing block 4. The lower substrate rest part PASS8, on the other hand, is used for the transport of a substrate W from the interface block 5 to the development processing block 4. Specifically, the transport robot TR3 of the development processing block 4 receives the substrate W placed on the substrate rest part PASS8 by the transport robot TR4 of the interface block 5. Each of the substrate rest parts PASS7 and PASS8 includes both an open side facing the transport robot TR3 of the development processing block 4 and an open side facing the transport robot TR4 of the interface block 5.

Next, the interface block 5 will be described. The interface block 5 is a block provided adjacent to the development processing block 4. The interface block 5 receives a substrate W with the resist film formed thereon by the resist coating process from the resist coating block 3 to transfer the substrate W to the exposure unit EXP which is an external apparatus separate from the substrate processing apparatus according to the present invention. Also, the interface block 5 receives an exposed substrate W from the exposure unit EXP to transfer the exposed substrate W to the development processing block 4. The interface block 5 in this preferred embodiment comprises a transport mechanism 55 for transferring and receiving a substrate W to and from the exposure unit EXP, a pair of edge exposure units EEW1 and EEW2 for exposing the periphery of a substrate W formed with the resist film, and the transport robot TR4 for transferring and receiving a substrate W to and from the heating parts PHP7 to PHP 12 and cool plate CP14 provided in the development processing block 4 and the edge exposure units EEW1 and EEW2.

As shown in FIG. 2, each of the edge exposure units EEW1 and EEW2 (collectively referred to as an edge exposure part EEW, unless otherwise identified) includes a spin chuck 56 for rotating a substrate W in a substantially horizontal plane while holding the substrate W in a substantially horizontal position under suction, a light irradiator 57 for exposing the periphery of the substrate W held on the spin chuck 56 to light, and the like. The pair of edge exposure units EEW1 and EEW2 are arranged in vertically stacked relation in the center of the interface block 5. The transport robot TR4 provided adjacent to the edge exposure part EEW and the thermal processing tower 42 of the development processing block 4 is similar in construction to the above-mentioned transport robots TR1 to TR3.

As illustrated also in FIG. 2, a return buffer RBF for the return of substrates W is provided under the pair of edge exposure units EEW1 and EEW2, and the pair of vertically arranged substrate rest parts PASS9 and PASS10 are provided under the return buffer RBF. The return buffer RBF is provided to temporarily store a substrate W subjected to a post-exposure heating process in the heating parts PHP7 to PHP12 of the development processing block 4 if the development processing block 4 is unable to perform the development process on the substrate W because of some sort of malfunction and the like. The return buffer RBF includes a cabinet capable of storing a plurality of substrates W in tiers. The upper substrate rest part PASS9 is used for the transfer of a substrate W from the transport robot TR4 to the transport mechanism 55. The lower substrate rest part PASS10 is used for the transfer of a substrate W from the transport mechanism 55 to the transport robot TR4. The transport robot TR4 gains access to the return buffer RBF.

The transport mechanism 55 includes a movable base 55a movable horizontally in the Y direction, and a holding arm 55b mounted on the movable base 55a and for holding a substrate W, as illustrated in FIG. 2. The holding arm 55b is capable of moving vertically, pivoting and moving back and forth in the direction of the pivot radius relative to the movable base 55a. With such an arrangement, the transport mechanism 55 transfers and receives a substrate W to and from the exposure unit EXP, transfers and receives a substrate W to and from the substrate rest parts PASS9 and PASS 10, and stores and takes a substrate W into and out of a send buffer SBF for the sending of substrates W. The send buffer SBF is provided to temporarily store a substrate W prior to the exposure process if the exposure unit EXP is unable to accept the substrate W, and includes a cabinet capable of storing a plurality of substrates W in tiers.

A downflow of clean air is always supplied into the indexer block 1, the BARC block 2, the resist coating block 3, the development processing block 4, and the interface block 5 described above to thereby avoid the adverse effects of raised particles and gas flows upon the processes in the respective blocks 1 to 5. Additionally, a slightly positive pressure relative to the external environment of the substrate processing apparatus is maintained in each of the blocks 1 to 5 to prevent the entry of particles and contaminants from the external environment into the blocks 1 to 5.

The indexer block 1, the BARC block 2, the resist coating block 3, the development processing block 4 and the interface block 5 as described above are units into which the substrate processing apparatus of this preferred embodiment is divided in mechanical terms. The blocks 1 to 5 are assembled to individual block frames, respectively, which are in turn connected together to construct the substrate processing apparatus.

On the other hand, this preferred embodiment employs another type of units, that is, transport control units regarding the transport of substrates, aside from the blocks which are units based on the above-mentioned mechanical division. The transport control units regarding the transport of substrates are referred to herein as “cells.” Each of the cells comprises a transport robot responsible for the transport of substrates, and a transport destination part to which the transport robot transports a substrate. Each of the substrate rest parts described above functions as an entrance substrate rest part for the receipt of a substrate W into a cell or as an exit substrate rest part for the transfer of a substrate W out of a cell. The transfer of substrates W between the cells is carried out through the substrate rest parts. The transport robots constituting the cells include the substrate transfer mechanism 12 of the indexer block 1 and the transport mechanism 55 of the interface block 5.

The substrate processing apparatus in this preferred embodiment comprises six cells: an indexer cell, a BARC cell, a resist coating cell, a development processing cell, a post-exposure bake cell, and an interface cell. The indexer cell includes the table 11 and the substrate transfer mechanism 12, and is consequently similar in construction to the indexer block 1 which is one of the units based on the mechanical division. The BARC cell includes the bottom coating processor BRC, the pair of thermal processing towers 21 and the transport robot TR1. The BARC cell is also consequently similar in construction to the BARC block 2 which is one of the units based on the mechanical division. The resist coating cell includes the resist coating processor SC, the pair of thermal processing towers 31, and the transport robot TR2. The resist coating cell is also consequently similar in construction to the resist coating block 3 which is one of the units based on the mechanical division.

The development processing cell includes the development processor SD, the thermal processing tower 41, and the transport robot TR3. Because the transport robot TR3 cannot gain access to the heating parts PHP7 to PHP12 and the cool plate CP14 of the thermal processing tower 42 as discussed above, the development processing cell does not include the thermal processing tower 42. In this respect, the development processing cell differs from the development processing block 4 which is one of the units based on the mechanical division.

The post-exposure bake cell includes the thermal processing tower 42 positioned in the development processing block 4, the edge exposure part EEW positioned in the interface block 5, and the transport robot TR4 positioned in the interface block 5. That is, the post-exposure bake cell extends over the development processing block 4 and the interface block 5 which are units based on the mechanical division. In this manner, constituting one cell including the heating parts PHP7 to PHP12 for performing the post-exposure heating process and the transport robot TR4 allows the rapid transport of exposed substrates W into the heating parts PHP7 to PHP12 for the execution of the thermal process. Such an arrangement is preferred for the use of a chemically amplified resist which is required to be subjected to a heating process as soon as possible after the exposure of a substrate W in a pattern.

The substrate rest parts PASS7 and PASS8 included in the thermal processing tower 42 are provided for the transfer of a substrate W between the transport robot TR3 of the development processing cell and the transport robot TR4 of the post-exposure bake cell.

The interface cell includes the transport mechanism 55 for transferring and receiving a substrate W to and from the exposure unit EXP which is an external apparatus. The interface cell differs from the interface block 5 which is one of the units based on the mechanical division in that the interface cell does not include the transport robot TR4 and the edge exposure part EEW. The substrate rest parts PASS9 and PASS10 under the edge exposure part EEW are provided for the transfer of a substrate W between the transport robot TR4 of the post-exposure bake cell and the transport mechanism 55 of the interface cell.

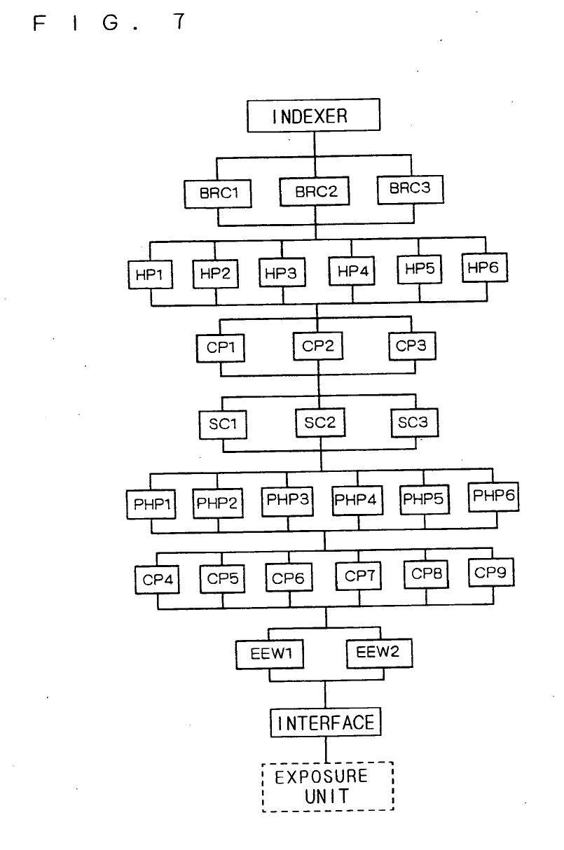

A control mechanism in the substrate processing apparatus of this preferred embodiment will be described. FIG. 6 is a schematic block diagram of the control mechanism. As shown in FIG. 6, the substrate processing apparatus of this preferred embodiment has a three-level control hierarchy composed of a main controller MC, cell controllers CC, and unit controllers. The main controller MC, the cell controllers CC and the unit controllers are similar in hardware construction to typical computers. Specifically, each of the controllers comprises a CPU for performing various computation processes, a ROM or read-only memory for storing a basic program therein, a RAM or readable/writable memory for storing various pieces of information therein, a magnetic disk for storing control applications and data therein, and the like.

The single main controller MC at the first level is provided for the entire substrate processing apparatus, and is principally responsible for the management of the entire substrate processing apparatus, the management of a main panel MP, and the management of the cell controllers CC. The main panel MP functions as a display for the main controller MC. Various commands may be entered into the main controller MC from a keyboard KB. The main panel MP may be in the form of a touch panel so that a user performs an input process into the main controller MC from the main panel MP.

The cell controllers CC at the second level are individually provided in corresponding relation to the six cells (the indexer cell, the BARC cell, the resist coating cell, the development processing cell, the post-exposure bake cell, and the interface cell). Each of the cell controllers CC is principally responsible for the control of the transport of substrates and the management of the units in a corresponding cell. Specifically, the cell controllers CC for the respective cells send and receive information in such a manner that a first cell controller CC for a first cell sends information indicating that a substrate W is placed on a predetermined substrate rest part to a second cell controller CC for a second cell adjacent to the first cell, and the second cell controller CC for the second cell having received the substrate W sends information indicating that the substrate W is received from the predetermined substrate rest part back to the first cell controller CC. Such sending and receipt of information are carried out through the main controller MC. Each of the cell controllers CC provides the information indicating that a substrate W is transported into a corresponding cell to a transport robot controller TC, which in turn controls a corresponding transport robot to circulatingly transport the substrate W in the corresponding cell in accordance with a predetermined procedure. The transport robot controller TC is a controller implemented by the operation of a predetermined application in the corresponding cell controller CC.

Examples of the unit controllers at the third level include a spin controller and a bake controller. The spin controller directly controls the spin units (the coating processing units and the development processing units) provided in a corresponding cell in accordance with an instruction given from a corresponding cell controller CC. Specifically, the spin controller controls, for example, a spin motor for a spin unit to adjust the number of revolutions of a substrate W. The bake controller directly controls the thermal processing units (the hot plates, the cool plates, the heating parts, and the like) provided in a corresponding cell in accordance with an instruction given from a corresponding cell controller CC. Specifically, the bake controller controls, for example, a heater incorporated in a hot plate to adjust a plate temperature and the like.

The host computer 100 connected via the LAN lines to the substrate processing apparatus ranks as a higher level control mechanism than the three-level control hierarchy provided in the substrate processing apparatus (see FIG. 1). The host computer 100 comprises a CPU for performing various computation processes, a ROM or read-only memory for storing a basic program therein, a RAM or readable/writable memory for storing various pieces of information therein, a magnetic disk for storing control applications and data therein, and the like. The host computer 100 is similar in construction to a typical computer. Typically, a plurality of substrate processing apparatuses according to this preferred embodiment are connected to the host computer 100. The host computer 100 provides a recipe containing descriptions about a processing procedure and processing conditions to each of the substrate processing apparatuses connected thereto. The recipe provided from the host computer 100 is stored in a storage part (e.g., a memory) of the main controller MC of each of the substrate processing apparatuses.

The exposure unit EXP is provided with a separate controller independent of the above-mentioned control mechanism of the substrate processing apparatus. In other words, the exposure unit EXP does not operate under the control of the main controller MC of the substrate processing apparatus, but controls its own operation alone. Such an exposure unit EXP also controls its own operation in accordance with a recipe received from the host computer 100, and the substrate processing apparatus performs processes synchronized with the exposure process in the exposure unit EXP.

The operation of the substrate processing apparatus of this preferred embodiment will be described. First, brief description will be given on a general procedure for the circulating transport of substrates W in the substrate processing apparatus. The processing procedure to be described below is in accordance with the descriptions of the recipe received from the host computer 100.

First, unprocessed substrates W stored in a cassette C are transported from the outside of the substrate processing apparatus into the indexer block 1 by an AGV (automatic guided vehicle) and the like. Subsequently, the unprocessed substrates W are transferred outwardly from the indexer block 1. Specifically, the substrate transfer mechanism 12 in the indexer cell (or the indexer block 1) takes an unprocessed substrate W out of a predetermined cassette C, and places the unprocessed substrate W onto the substrate rest part PASS1. After the unprocessed substrate W is placed on the substrate rest part PASS1, the transport robot TR1 of the BARC cell uses one of the holding arms 6a and 6b to receive the unprocessed substrate W. The transport robot TR1 transports the received unprocessed substrate W to one of the coating processing units BRC1 to BRC3. In the coating processing units BRC1 to BRC3, the substrate W is spin-coated with the coating solution for the anti-reflective film.

After the completion of the coating process, the transport robot TR1 transports the substrate W to one of the hot plates HP1 to HP6. Heating the substrate W in the hot plate dries the coating solution to form the anti-reflective film serving as the undercoat on the substrate W. Thereafter, the transport robot TR1 takes the substrate W from the hot plate, and transports the substrate W to one of the cool plates CP1 to CP3, which in turn cools down the substrate W. In this step, one of the cool plates WCP may be used to cool down the substrate W. The transport robot TR1 places the cooled substrate W onto the substrate rest part PASS3.

Alternatively, the transport robot TR1 may be adapted to transport the unprocessed substrate W placed on the substrate rest part PASS 1 to one of the adhesion promotion processing parts AHL1 to AHL3. In the adhesion promotion processing parts AHL1 to AHL3, the substrate W is thermally processed in a vapor atmosphere of HMDS, whereby the adhesion of the resist film to the substrate W is promoted. The transport robot TR1 takes out the substrate W subjected to the adhesion promotion process, and transports the substrate W to one of the cool plates CP1 to CP3, which in turn cools down the substrate W. Because no anti-reflective film is to be formed on the substrate W subjected to the adhesion promotion process, the cooled substrate W is directly placed onto the substrate rest part PASS3 by the transport robot TR1.

A dehydration process may be performed prior to the application of the coating solution for the anti-reflective film. In this case, the transport robot TR1 transports the unprocessed substrate W placed on the substrate rest part PASS1 first to one of the adhesion promotion processing parts AHL1 to AHL3. In the adhesion promotion processing parts AHL1 to AHL3, a heating process (dehydration bake) merely for dehydration is performed on the substrate W without supplying the vapor atmosphere of HMDS. The transport robot TR1 takes out the substrate W subjected to the heating process for dehydration, and transports the substrate W to one of the cool plates CP1 to CP3, which in turn cools down the substrate W. The transport robot TR1 transports the cooled substrate W to one of the coating processing units BRC1 to BRC3. In the coating processing units BRC1 to BRC3, the substrate W is spin-coated with the coating solution for the anti-reflective film. Thereafter, the transport robot TR1 transports the substrate W to one of the hot plates HP1 to HP6. Heating the substrate W in the hot plate forms the anti-reflective film serving as the undercoat on the substrate W. Thereafter, the transport robot TR1 takes the substrate W from the hot plate, and transports the substrate W to one of the cool plates CP1 to CP3, which in turn cools down the substrate W. Then, the transport robot TR1 places the cooled substrate W onto the substrate rest part PASS3.

After the substrate W is placed on the substrate rest part PASS3, the transport robot TR2 in the resist coating cell receives the substrate W, and transports the substrate W to one of the coating processing units SC1 to SC3. In the coating processing units SC1 to SC3, the substrate W is spin-coated with the resist. Because the resist coating process requires precise substrate temperature control, the substrate W may be transported to one of the cool plates CP4 to CP9 immediately before being transported to the coating processing units SC1 to SC3.

After the completion of the resist coating process, the transport robot TR2 transports the substrate W to one of the heating parts PHP1 to PHP6. In the heating parts PHP1 to PHP6, heating the substrate W removes a solvent component from the resist to form a resist film on the substrate W. Thereafter, the transport robot TR2 takes the substrate W from the one of the heating parts PHP1 to PHP6, and transports the substrate W to one of the cool plates CP4 to CP9, which in turn cools down the substrate W. Then, the transport robot TR2 places the cooled substrate W onto the substrate rest part PASS5.

After the substrate W with the resist film formed thereon by the resist coating process is placed on the substrate rest part PASS5, the transport robot TR3 in the development processing cell receives the substrate W, and places the substrate W onto the substrate rest part PASS7 without any processing of the substrate W. Then, the transport robot TR4 in the post-exposure bake cell receives the substrate W placed on the substrate rest part PASS7, and transports the substrate W to one of the edge exposure units EEW1 and EEW2. In the edge exposure units EEW1 and EEW2, a peripheral edge portion of the substrate W is exposed to light. The transport robot TR4 places the substrate W subjected to the edge exposure process onto the substrate rest part PASS9. The transport mechanism 55 in the interface cell receives the substrate W placed on the substrate rest part PASS9, and transports the substrate W into the exposure unit EXP. The substrate W transported into the exposure unit EXP is subjected to the pattern exposure process. Because the chemically amplified resist is used in this preferred embodiment, an acid is formed by a photochemical reaction in the exposed portion of the resist film formed on the substrate W. The substrate W subjected to the edge exposure process may be transported into the cool plate CP14 by the transport robot TR4 and subjected to a cooling process therein before being transported to the exposure unit EXP.

The exposed substrate W subjected to the pattern exposure process is transported from the exposure unit EXP back to the interface cell again. The transport mechanism 55 places the exposed substrate W onto the substrate rest part PASS10. After the exposed substrate W is placed on the substrate rest part PASS10, the transport robot TR4 in the post-exposure bake cell receives the substrate W, and transports the substrate W to one of the heating parts PHP7 to PHP12. In the heating parts PHP7 to PHP12, the heating process (post-exposure bake) is performed which causes reactions such as crosslinking, polymerization and the like of the resist resin to proceed by using a product formed by the photochemical reaction during the exposure process as an acid catalyst, thereby locally changing the solubility of only the exposed portion of the resist resin in the developing solution. The local transport mechanism (the transport mechanism in the one of the heating parts PHP7 to PHP12; see FIG. 1) having a cooling mechanism transports the substrate W subjected to the post-exposure bake process thereby to cool the substrate W, whereby the above-mentioned chemical reaction stops. Subsequently, the transport robot TR4 takes the substrate W from the one of the heating parts PHP7 to PHP12, and places the substrate W onto the substrate rest part PASS8.

After the substrate W is placed on the substrate rest part PASS8, the transport robot TR3 in the development processing cell receives the substrate W, and transports the substrate W to one of the cool plates CP10 to CP13. In the cool plates CP10 to CP13, the substrate W subjected to the post-exposure bake process is further cooled down and precisely controlled at a predetermined temperature. Thereafter, the transport robot TR3 takes the substrate W from the one of the cool plates CP10 to CP13, and transports the substrate W to one of the development processing units SD1 to SD5. In the development processing units SD1 to SD5, the developing solution is applied onto the substrate W to cause the development process to proceed. After the completion of the development process, the transport robot TR3 transports the substrate W to one of the hot plates HP7 to HP11, and then transports the substrate W to one of the cool plates CP10 to CP13.

Thereafter, the transport robot TR3 places the substrate W onto the substrate rest part PASS6. The transport robot TR2 in the resist coating cell transfers the substrate W from the substrate rest part PASS6 onto the substrate rest part PASS4 without any processing of the substrate W. Next, the transport robot TR1 in the BARC cell transfers the substrate W from the substrate rest part PASS4 onto the substrate rest part PASS2 without any processing of the substrate W, whereby the substrate W is stored in the indexer block 1. Then, the substrate transfer mechanism 12 in the indexer cell stores the processed substrate W held on the substrate rest part PASS2 into a predetermined cassette C. Thereafter, the cassette C in which a predetermined number of processed substrates W are stored is transported to the outside of the substrate processing apparatus. Thus, a series of photolithography processes are completed.

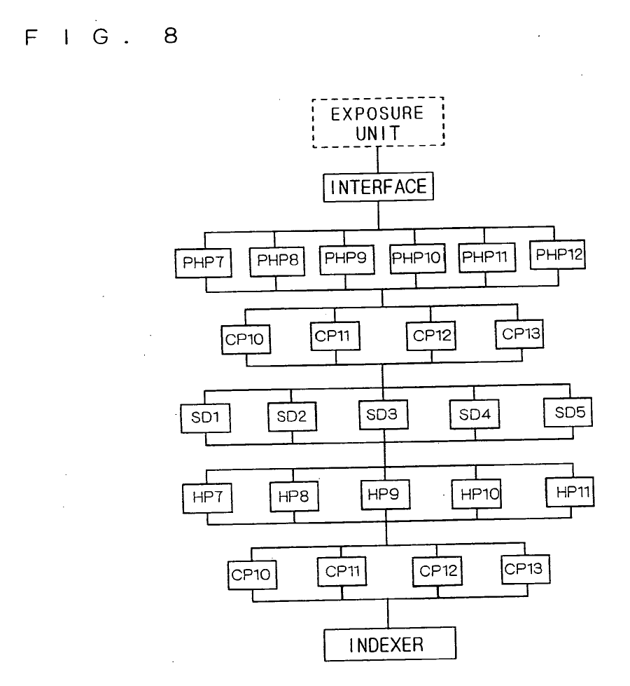

The series of photolithography processes as mentioned above include a multiplicity of parallel processes which in turn are executed by a plurality of parallel processing parts. FIGS. 7 and 8 are diagrams showing the parallel processing parts in the substrate processing apparatus according to this preferred embodiment. FIG. 7 shows the parallel processing parts for executing the parallel processes prior to the exposure process in the exposure unit EXP, and FIG. 8 shows the parallel processing parts for executing the parallel processes after the exposure process. In FIGS. 7 and 8, a plurality of processing units (substrate processing parts) shown as arranged in each row in parallel side-by-side relationship are a group of parallel processing parts for performing a process under the same condition in the same processing step described in a recipe. For example, the three coating processing units SC1, SC2 and SC3 shown in FIG. 7 are a group of parallel processing parts for executing the resist coating process under the same condition in the resist coating process step. Similarly, the six heating parts PHP7 to PHP12 shown in FIG. 8 are a group of parallel processing parts for executing the heating process under the same condition in the post-exposure heating processing step. The parallel processing parts for executing the parallel processes are shown as arranged in top-to-bottom order in accordance with the sequence of the above-mentioned photolithography processes.

Because these parallel processing parts in each group are provided for executing a process under the same condition, the same process is executed in the parallel processing parts in each group. For example, in the coating processing units SC1 and SC3, the resist solution is discharged at the same flow rate at the same time under the same atmosphere temperature and humidity conditions, and substrates are rotated for the same time period at the same rpm. Thus, the transport of a substrate W to be processed to whichever parallel processing part essentially makes no difference. Essentially the same processing result is obtained, for example, even when the substrate W is transported to a parallel processing part which is vacant in the stage of execution of each parallel process.

However, a slight difference inevitably exists between the parallel processing parts in each group, and causes slight variations in processing results between substrates, as described above. For example, the thickness of a resist film formed on a substrate subjected to the resist coating process in the coating processing unit SC1 and the thickness of a resist film formed on a substrate subjected to the resist coating process in the coating processing units SC3 produce different results from a microscopic viewpoint. In the light of the required level of the quality control in recent years, even such slight variations in processing results have been perceived as a problem, also as described above.

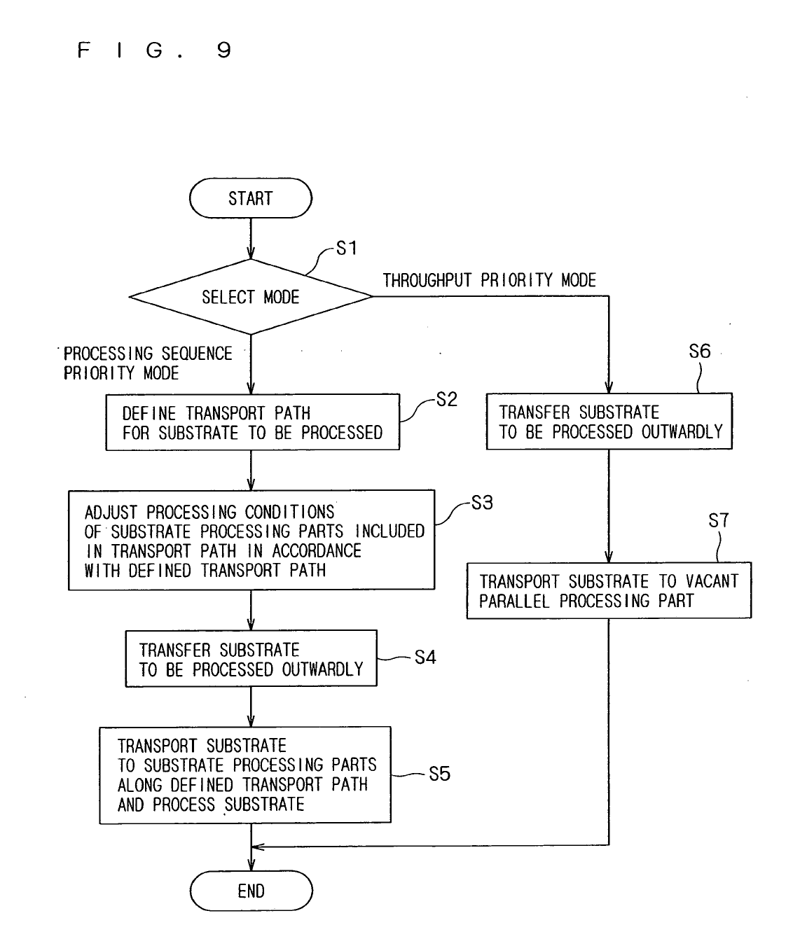

To solve the problem, the substrate processing apparatus according to the present invention executes processing to be described below. FIG. 9 is a flow chart showing a procedure for the processing in the substrate processing apparatus according to the present invention. First, prior to the outward transfer of an unprocessed substrate W from the indexer block 1, an operator of the apparatus selects a substrate transport mode to enter the selected mode into the substrate processing apparatus (in Step S1). This mode selection may be carried out either by direct entry from the main panel MP or through the host computer 100. There are two selectable modes: a “throughput priority mode” and a “processing sequence priority mode.”

When the “processing sequence priority mode” is selected, the procedure proceeds to Step S2 in which a transport path for the unprocessed substrate W is previously defined prior to the outward transfer of the unprocessed substrate W from the indexer block 1. The transport path is defined by the main controller MC. The definition of the transport path is carried out by determining to which of the parallel processing parts for performing each parallel process a substrate W to be processed is to be transported. Specifically, to which of the three coating processing units BRC1 to BRC3 for performing the parallel process of applying the coating solution for the anti-reflective film the substrate W is to be transported is determined. Next, to which of the six hot plates HP1 to HP6 for performing the subsequent heating process (which is another parallel process) the substrate W is to be transported is determined. For subsequent parallel processes, to which of the parallel processing parts the substrate W is to be transported is determined, whereby the transport path is defined. Any criterion may be used to determine to which of the parallel processing parts the substrate W is to be transported. As an example, because it is determined that a substrate to be processed immediately before the substrate W is to be transported to the coating processing unit BRC1, a determination may be made that the substrate W is to be transported to the coating processing unit BRC2 different from the coating processing unit BRC1. It is not always necessary to define the transport path in which a first parallel processing part for performing a first parallel process and a second parallel processing part for performing a second parallel process are in a one-to-one fixed correspondence with each other. For example, while a first transport path is defined for a first substrate W so that the first substrate W is transported to the hot plate HP1 after being transported to the coating processing unit BRC1, a second transport path may be defined for a second substrate W so that the second substrate W is transported to the hot plate HP3 after being transported to the coating processing unit BRC1.

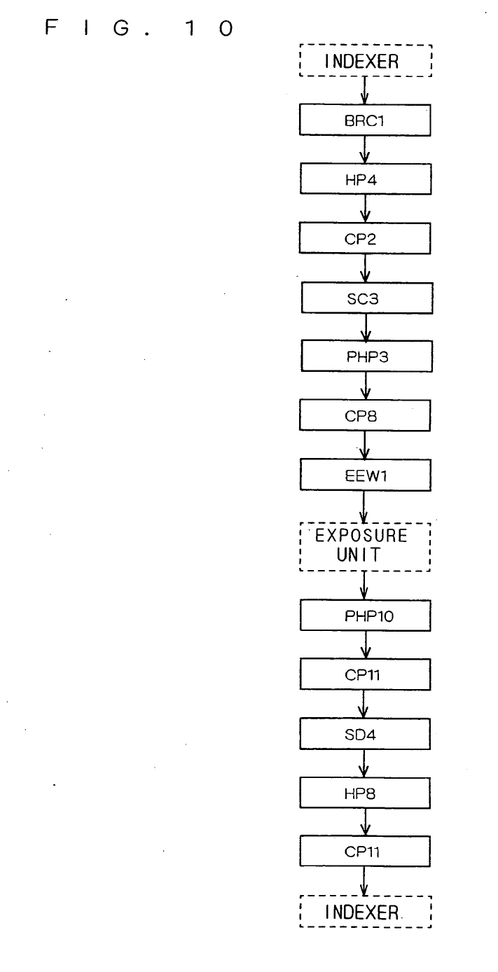

FIG. 10 shows an example of the transport paths defined in a manner mentioned above. In FIG. 10, parallel processing parts determined as destinations to which the substrate W is to be transported are surrounded by solid lines. Only one type of the transport paths are shown in FIG. 10. The number of definable different transport path types is equal to the product of the numbers of parallel processing parts for performing the respective parallel processes.

Next, the procedure proceeds to Step S3 in which, based on the defined transport path, an adjustment is made to processing conditions (standard processing conditions) established in the recipe for the substrate processing parts included in the transport path and for performing the processes in the steps before and after the exposure process. A corresponding unit controller adjusts a processing condition established for each substrate processing part in accordance with an instruction given from a corresponding cell controller. The conditions described in the recipe given from the host computer 100 are standard settings for the processing conditions to be established for the substrate processing parts. For example, when a post-exposure heating processing temperature of 110° C. is described in the recipe given from the host computer 100, the standard temperature is also 110° C. for the six heating parts PHP7 to PHP 12 for executing the post-exposure heating process. The conditions described in the recipe provides a desirable processing result (referred to hereinafter as a “standard processing result”) when the processing precisely conforms to the conditions.

In Step S3, the processing conditions established in the recipe for the substrate processing parts are adjusted so as to provide the standard processing result when the substrate W is transported along the transport path defined in Step S2. Adjustment information about the degree to which the processing conditions established for the substrate processing parts should be adjusted to provide the standard processing result is previously examined and acquired for each transport path type by experiment, and stored, for example, in the storage part of the main controller MC. Each of the cell controllers reads the adjustment information corresponding to the type of the defined transport path from the storage part of the main controller MC, and gives an instruction to a corresponding unit controller in accordance with the adjustment information thereby to adjust the processing conditions established for the substrate processing parts. As an example, when the transport path as shown in FIG. 10 is defined in Step S2, the adjustment information corresponding to the transport path of FIG. 10 is read. In accordance with the read adjustment information, for example, the rpm of the substrate established for the coating processing unit SC3 can be adjusted to a value slightly higher than the standard rpm described in the recipe, and the temperature established for the heating part PHP10 can be adjusted to a value slightly lower than the standard temperature described in the recipe. Adjustable items include, for example, the rpm of a substrate, the time of rotation, the temperature of an atmosphere, the humidity of an atmosphere, a flow rate at which a liquid is discharged, the total amount of discharged liquid, the timing of the liquid discharge, the temperature of a liquid and the like for spin units (the coating processing units and the development processing units), and the temperature, processing time and the like for the thermal processing units (the hot plates, the cool plates, the heating parts and the like).

Such an adjustment may be said to be a fine-tuning of the processing conditions (standard processing conditions) described in the recipe. If any transport path is defined in Step S2, the transport of the substrate W along the transport path after the adjustment in Step S3 provides the standard processing result.

After the adjustment is made to the processing conditions established for the substrate processing parts, the procedure proceeds to Step S4 in which the above-mentioned unprocessed substrate W is transferred outwardly from the indexer block 1. The outwardly transferred substrate W is transported and processed along the transport path defined in Step S2 (in Step S5). When the “processing sequence priority mode” is selected, the transport of the substrate along the transport path defined in Step S2 is ensured. For example, if the heating part PHP 10 is occupied at the time of the execution of the post-exposure heating processing step on the assumption that the transport path of FIG. 10 is defined in Step S2, the above-mentioned substrate W is controlled to be held in a standby condition until the heating part PHP 10 becomes unoccupied and to be transported to the heating part PHP 10 without fail.

In this manner, the substrate is transported faithfully along the transport path defined in Step S2, and a series of photolithography processes are executed under the processing conditions adjusted in Step S3.

On the other hand, when the “throughput priority mode” is selected, the unprocessed substrate W is immediately transferred outwardly from the indexer block 1 (in Step S6). The substrate W is transported sequentially to the substrate processing parts in accordance with the processing procedure described in the recipe. In the “throughput priority mode,” the transport path is not previously determined, but the substrate W is basically transported to a vacant parallel processing part in each parallel processing step (in Step S7). For example, if the heating part PHP9 is vacant at the time of the execution of the post-exposure heating processing step, the substrate W is transported to the heating part PHP9. In this manner, the substrate is transported sequentially to the substrate processing parts, and the series of photolithography processes are executed.

A comparison between the “processing sequence priority mode” and the “throughput priority mode” described above is as follows. When the “processing sequence priority mode” is selected, the substrate is transported faithfully in accordance with the transport path defined prior to the outward transfer of the substrate. The processing conditions established for the substrate processing parts included in the transport path are adjusted so as to provide the standard processing result when the substrate is transported along the transport path. Therefore, a constant processing result is always produced. In other words, the variations in processing results between the substrates passing through different parallel processing pars are reduced. On the other hand, when the “throughput priority mode” is selected, the substrate W is always transported to a vacant parallel processing part in each parallel processing step. This prevents the throughput in the “throughput priority mode” from becoming lower than that at least in the “processing sequence priority mode.” However, because to which parallel processing part the substrate W is to be transported is not previously determined, the “throughput priority mode” cannot eliminate the influence of the slight difference between the parallel processing parts. Therefore, there is a likelihood that slight variations in processing results occur between the substrates in the “throughput priority mode.”

Thus, the “processing sequence priority mode” may be selected for a substrate intended to provide a stable processing result with less variations, whereas the “throughput priority mode” may be selected for a substrate whose processing result is not required to have a high degree of precision.

Although the preferred embodiment according to the present invention is described hereinabove, the present invention is not limited to the above-mentioned specific embodiment. For example, the combination of the parallel processing parts is not limited to those shown in FIGS. 7 and 8, but any combination may be used in accordance with the time required for the parallel processes and the like.

Additionally, the construction of the substrate processing apparatus according to the present invention is not limited to that shown in FIGS. 1 through 4. However, various modifications may be made to the construction of the substrate processing apparatus if a transport robot circulatingly transports a substrate W to a plurality of processing parts whereby predetermined processes are performed on the substrate W.

While the invention has been described in detail, the foregoing description is in all aspects illustrative and not restrictive. It is understood that numerous other modifications and variations can be devised without departing from the scope of the invention.

1.-4. (canceled)

5. A substrate processing method for transferring a substrate from an indexer part to a plurality of substrate processing parts and for performing a process prior to an exposure process including a resist coating process and a process after an exposure process including a development process on the substrate, said substrate processing method comprising the steps of:
determining to which of a plurality of parallel processing parts an unprocessed substrate is to be transported to thereby previously define a transport path for the unprocessed substrate before the unprocessed substrate is transferred from said indexer part to said plurality of substrate processing parts, said plurality of parallel processing parts being included in said plurality of substrate processing parts and performing a process under the same condition in the same processing step,
adjusting a processing condition established for at least one of said plurality of substrate processing parts which is included in said transport path and which performs a process in a step prior to an exposure process based on said defined transport path, and
transferring said unprocessed substrate sequentially to at least one of said plurality of substrate processing parts included in said transport path among said plurality of substrate processing parts along said defined transport path.

6. The substrate processing method according to claim 5, further comprising:
a step of accepting an input of one of a processing sequence priority mode and a throughput priority mode as a mode for a substrate processing procedure; and
transporting a substrate along said defined transport path when said processing sequence priority mode is selected and transporting a substrate to a vacant one of said plurality of parallel processing parts without the definition of the transport path when said throughput priority mode is selected.

7. A substrate processing method for transferring a substrate from an indexer part to a plurality of substrate processing parts and for performing a process prior to an exposure process including a resist coating process and a process after an exposure process including a development process on the substrate, said substrate processing method comprising the steps of:
determining to which of a plurality of parallel processing parts an unprocessed substrate is to be transported to thereby previously define a transport path for the unprocessed substrate before the unprocessed substrate is transferred from said indexer part to said plurality of substrate processing parts, said plurality of parallel processing parts being included in said plurality of substrate processing parts for performing a process under the same condition in the same processing step,
adjusting a processing condition established for at least one of said plurality of substrate processing parts which is included m said transport path and which performs a process in a step after an exposure process based on said defined transport path, and
transferring said unprocessed substrate sequentially to at least one of said plurality of substrate processing parts included in said transport path among said plurality of substrate processing parts along said defined transport path.

8. The substrate processing method according to claim 7, further comprising:
a step of accepting an input of one of a processing sequence priority mode and a throughput priority mode as a mode for a substrate processing procedure; and
transporting a substrate along said defined transport path when said processing sequence priority mode is selected and transporting a substrate to a vacant one of said plurality of parallel processing parts without the definition of the transport path when said throughput priority mode is selected.
